(19) United States
(12) Patent Application Publication
(10) Pub. No.: US 2010/0155880 A1
(43) Pub. Date: Jun. 24, 2010

(54) Back gate doping for SOI substrates

(75) Inventors: Ibrahim Ban, Beaverton, OR (US); Peter G. Tolchinsky, Beaverton, OR (US); Irwin Yablok, Portland, OR (US)

Correspondence Address: INTEL CORPORATION;c/o CPA Global, P.O. BOX 52050, MINNEAPOLIS, MN, 55402, US

(73) Assignee: Intel Corporation

(21) Appl. No.: 12/317,449

(22) Filed: Dec. 23, 2008

(51) Int. Cl. H01L 27/12

(52) U.S. Cl. 257/506; 257/E27.112

(57) ABSTRACT

A silicon-on-insulator (SOI) substrate comprises a base silicon substrate having a back gate region, wherein the back gate region has a first dopant concentration that is greater than 1×10¹⁷ cm⁻³, a nitrogen layer adjacent to the back gate region of the base silicon substrate, a BOX layer adjacent to the nitrogen layer, and a thin silicon device layer adjacent to the BOX layer, wherein the thin silicon device layer has a first dopant concentration that is less than 1×10^{17 cm}⁻³. In some implementations, the thin silicon device layer has a first dopant concentration that is less than 1×10¹⁵ cm⁻³.

### BACKGROUND

Silicon-on-insulator (SOI) wafers typically include an insulating layer (e.g., silicon dioxide) sandwiched between a thin silicon device layer and a thicker base silicon substrate. The insulating layer is therefore “buried” within the silicon and is referred to as a buried oxide (BOX) layer. Integrated circuit devices (e.g., MOSFET devices) may be formed on the thin silicon device layer. The BOX layer reduces capacitance so the amount of electrical charge that each transistor has to move during a switching operation is generally reduced, thereby making the transistor faster and allowing it to switch using less energy. For low voltage operation of floating body cells (FBC), a heavily P-doped (P++) back gate is used. The back gate refers to a region of the base silicon substrate that is adjacent to the BOX layer. Doping the back gate therefore refers to doping the base silicon substrate at the substrate/BOX interface. A generic FBC device having a P++ back gate is shown in FIG. 1.

Ion implantation processes are used to form the BOX layer and to dope the back gate. For instance, oxygen and nitrogen can be implanted into a bulk silicon wafer using an ion beam process. The wafer is then annealed to form a “separation by implantation of oxygen and nitrogen” wafer, known as a SIMON wafer. Similarly, the ion implantation process may only implant oxygen (to form a SIMOX wafer) or only nitrogen (to form a SIMNI wafer). After the BOX layer is formed, a second ion implantation process is used to dope the back gate. Unfortunately, these ion implantation processes can cause a significant amount of damage to the thin silicon device layer where the integrated circuit devices are to be formed. The back gate doping can also cause damage to the BOX layer. Furthermore, conventional SOI wafers built with silicon dioxide as the insulating layer tend to have poor etch resistance, which presents a problem since etching processes are necessary to form the devices. As such, an alternate process to form SOI wafers having a doped back gate is needed.

### BRIEF DESCRIPTION OF THE DRAWINGS

FIG. 1 shows a conventional floating body cell device having a P+ back gate.

FIG. 2 is a method of forming an SOI wafer having a heavily doped back gate in accordance with an implementation of the invention.

FIGS. 3A through 3H illustrate structures formed when the method of FIG. 2 is carried out.

FIG. 4 is a method of forming an SOI wafer having a heavily doped back gate in accordance with another implementation of the invention.

FIGS. 5A through 5E illustrate structures formed when the method of FIG. 4 is carried out.

FIG. 5F illustrates a second nitrogen layer formed within the SOI wafer in accordance with an implementation of the invention.

### DETAILED DESCRIPTION

Described herein are systems and methods of forming a silicon-on-insulator (SOI) wafer. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide a process flow that forms an SOI substrate having a heavily doped P++ back gate and a substantially undoped thin silicon device layer. The processes described herein are non-invasive and therefore cause relatively less ion implantation damage to the thin silicon device layer.

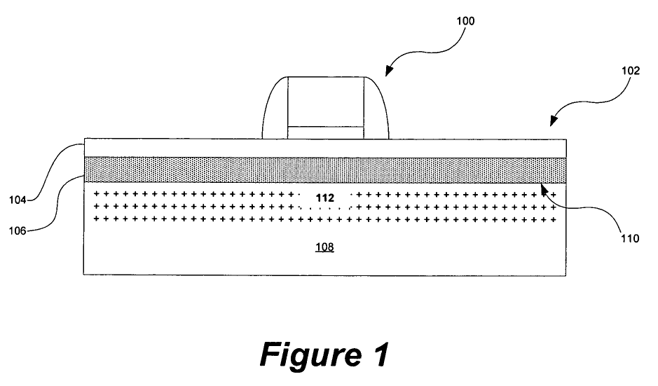

FIG. 1 shows a conventional floating body cell (FBC) device 100 having a P++ back gate. The FBC 100 is built on a conventional SOI wafer 102, which includes a thin silicon device layer 104, a BOX layer 106, and a thicker base silicon substrate 108. The base silicon substrate 108 is P++ doped along an interface 110 where the base silicon substrate 108 meets the BOX layer 106; this P++ doped region provides a back gate 112 for the FBC device.

The ion implantation damage caused by doping the back gate causes etch rate changes to the thin silicon device layer 104 and BOX layer 106. This is problematic because if the oxide is etched at a much higher rate due to implant damage, then gate planarization is much harder to achieve, which impacts subsequent replacement metal gate (RMG) processes.

A larger issue is that the ion implantation damage creates defects in the SOI substrate that lead to implant “straggle,” thereby allowing the implanted ions to be somewhat mobile within the SOI substrate. Unfortunately, this straggle prevents a heavy concentration of ions from gathering in the back gate region 112 of the base silicon substrate 108 because the ions tend to spread out to other areas. One of these areas is the thin silicon device layer 104 where a low concentration of the implanted ions will develop. Compounding this problem is the fact that a residual concentration of these ions will already be present in the thin silicon device layer 104 due to some of the ions not penetrating all the way through to the base silicon substrate 108 during the back gate ion implantation process.

The ions, such as boron ions, are undesirable in the thin silicon device layer 104 due to their negative effect on random dopant fluctuations (RDF) and junction leakage. As such, conventional implantation processes for forming BOX layers and doped back gates represent a compromise where the back gate 112 has a lower ion concentration than desired and the thin silicon device layer 104 has a higher ion concentration than desired. For example, a typical SOI substrate with a doped back gate will have an average boron concentration of between 4×10¹⁷ cm⁻³ and 4×10¹⁸ cm⁻³ in the thin silicon device layer, and will have an average boron concentration of between 2×10¹⁸ cm⁻³ and 3×10¹⁹ cm⁻³ in the base silicon substrate (i.e., in the back gate region of the base silicon substrate).

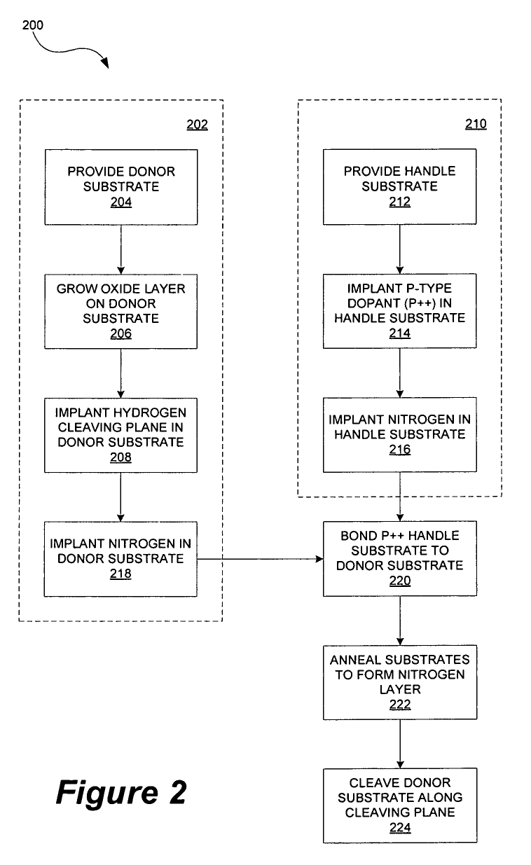

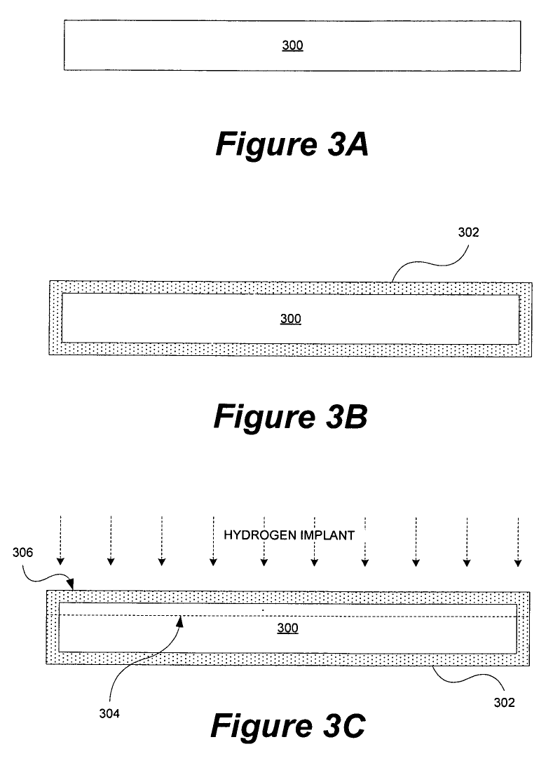

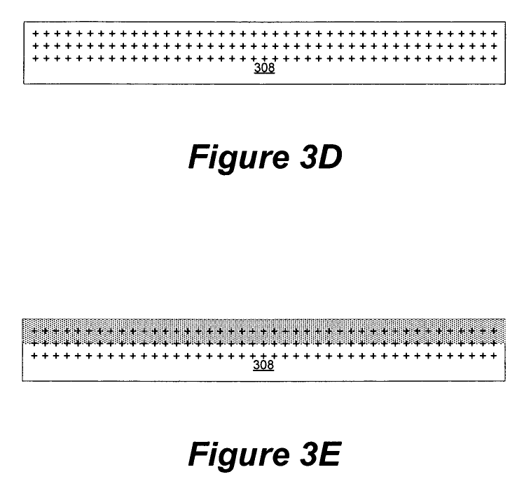

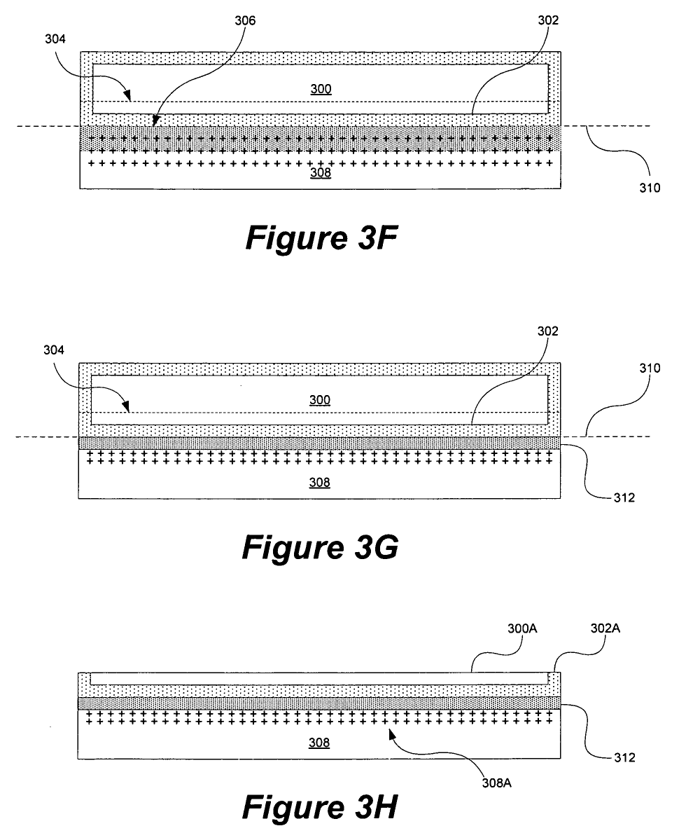

FIG. 2 is a method 200, according to one implementation of the invention, of forming an SOI wafer having a heavily doped P++ region that serves as a back gate for integrated circuit (IC) devices, such as FBCs. FIGS. 3A through 3E illustrate structures formed when the method of FIG. 2 is carried out.

The method 200 includes preparing a donor substrate (process 202 of FIG. 2). A donor substrate is generally a crystalline semiconductor substrate that is formed using silicon, referred to simply as a silicon wafer. In other implementations, the donor substrate may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate may be formed are described here, any material that may serve as a foundation upon which a semiconductor device may be built falls within the spirit and scope of the present invention. In accordance with implementations of the invention, the donor substrate will provide both a thin silicon device layer and a BOX layer for the SOI substrate being formed. FIG. 3A illustrates a donor substrate 300.

After a donor substrate is provided (process 204 of FIG. 2), a thin oxide layer is grown or deposited on the surface of the donor substrate (206). If the donor substrate is silicon, the oxide formed is silicon dioxide. Alternate oxides may be grown or epitaxially deposited in further implementations, especially if the substrate includes materials other than silicon. In some implementations, the oxide layer may be grown to a thickness between around 10 Angstroms (Å) and 500 Å, more preferably between 25 Å and 250 Å. FIG. 3B illustrates an oxide layer 302 that has been formed on the surface of the donor semiconductor substrate 300. Methods of growing or depositing an oxide on a semiconductor substrate are well known.

An ion implantation process is then carried out on a first surface of the donor substrate to deposit a thin layer of hydrogen (H) atoms within the donor substrate, thereby forming a hydrogen cleaving plane (208). Methods of forming a hydrogen cleaving plane within a semiconductor substrate are well known in the art. The depth of the cleaving plane (relative to the first surface of the donor substrate) is dependent on the desired thickness of the thin silicon device layer in the final SOI substrate of the invention. FIG. 3C illustrates a cleaving plane 304 formed within the donor substrate 300. A first surface 306 of the substrate 300, through which the ion implantation process may occur, is denoted as well.

The method 200 also includes preparing a heavily doped P++ handle substrate (210). A handle substrate is a semiconductor substrate, typically a crystalline silicon wafer, that may be heavily P-doped (i.e., P++ doped). In a subsequent process described below, the P++ handle substrate will be bonded to the donor substrate to provide a heavily doped back gate for the SOI substrate being formed in accordance with an implementation of the invention.

Preparation of the handle substrate begins by providing or acquiring a handle substrate (212). If the handle substrate is already heavily doped (P++), then the method 200 may continue at process 216 below. Otherwise, the handle substrate undergoes an ion implantation process whereby a relatively heavy dose of a P-type dopant, such as boron, is implanted into the handle substrate (214). This relatively heavy dose of P-type dopant forms a P++ region in the handle substrate, which is now referred to as a P++ handle substrate. FIG. 3D illustrates a P++ handle substrate 308.

Although in the implementations described herein the handle substrate is P-doped, it should be noted that in some implementations N-type doping may be used instead (to form an N++ handle substrate). In alternate implementations, the handle substrate may be formed using alternate materials, which may or may not be combined with silicon, that include but are not limited to germanium, indium antimonide, lead telluride, indium arsenide, indium phosphide, gallium arsenide, or gallium antimonide. Therefore the scope of the invention is not limited to P++ handle substrates.

In accordance with implementations of the invention, at least one nitrogen layer is incorporated into the final SOI substrate to substantially prevent the migration or diffusion of the P-type dopant (e.g., boron) out of the P++ handle substrate. For instance, once the donor and handle substrates are bonded, boron in the P++ handle substrate may diffuse into the donor substrate. Since the donor substrate includes the thin silicon device layer that is used to form integrated circuit devices, the presence of boron in the donor substrate is highly undesirable. In accordance with implementations of the invention, the inclusion of a nitrogen layer substantially prevents boron from diffusing out of the P++ handle substrate, thereby maintaining a relatively low or negligible boron concentration in the thin silicon device layer.

The first step in forming a nitrogen layer is to implant nitrogen into one or both of the P++ handle substrate and the donor substrate. In one implementation, nitrogen may be implanted into the P++ handle substrate in addition to the P-type dopant (216). The nitrogen may be implanted using an ion implantation process or a diffusion process. Ion implantation processes are well known in the art. A nitrogen diffusion process embeds nitrogen into the substrate using a high temperature thermal anneal under a nitrogen atmosphere. Nitrogen diffuses into the SOI substrate during the anneal, which causes significantly less damage to the substrate than an ion implantation process. The annealing process may be performed at a temperature between 800° C. and 1350° C. for a duration of time that ranges from 10 minutes to 5 hours. For instance, the P++ handle substrate may be exposed to a flowing nitrogen gas while annealed at a temperature of 1200° C. for 1 to 2 hours. FIG. 3E illustrates the P++ handle substrate 308 after a nitrogen implant, represented by the shaded area.

In another implementation, nitrogen may be implanted into the donor substrate (218). Again, an ion implantation process or a diffusion process may be used to implant nitrogen into the donor substrate. The nitrogen will be implanted through the same first surface of the donor substrate that the hydrogen cleaving atoms were implanted through. In further implementations, nitrogen may be implanted into both the donor substrate and the P++ handle substrate.

After the nitrogen is implanted, the P++ handle substrate is bonded to the first surface of the donor substrate (220). The P++ handle substrate is therefore bonded to the oxide layer of the donor substrate. Conventional wafer bonding processes, such as a thermal anneal, may be used. Methods of bonding two semiconductor wafers together are well known in the art. Generally, the grown oxide of the donor substrate is bonded to native oxide of the P++ handle substrate. FIG. 3F illustrates the P++ handle substrate 308 bonded to the first surface 306 of the donor substrate 300 along an interface 310.

In accordance with implementations of the invention, a high temperature annealing process is used to drive the implanted nitrogen to the interface between the donor substrate and the P++ handle substrate where the nitrogen accumulates and forms a nitrogen layer (222). This annealing process may be the same process that bonds the donor and handle wafers together or it may be a subsequent annealing process. As indicated above, this nitrogen layer effectively prevents boron, or any other P-type dopant, from diffusing out of the P++ handle substrate and into the donor substrate. Furthermore, this or another annealing process may also drive P++ dopant ions to the same interface and therefore increase the P++ doping concentration at the back gate. FIG. 3G illustrates a nitrogen layer 312 that had formed along the interface 310 between the thin oxide layer 302 and the P++ handle substrate 308.

Finally, after the bonding process is complete, the donor substrate is cleaved along the cleaving plane (224). This yields a final SOI structure. The cleaved donor substrate provides the thin silicon device layer. The oxide layer provides the BOX layer. And the P++ handle substrate provides the base silicon substrate. The handle substrate is heavily P-doped, so there is P++ doping in the back gate region (i.e., along the interface between the base silicon substrate and the BOX layer).

FIG. 3H illustrates the final SOI wafer after the donor substrate 300 is cleaved. As shown, the cleaved donor substrate 300 now provides a thin silicon device layer 300A, the oxide layer 302 now provides a BOX layer 302A, and the handle substrate 308 now provides the base silicon substrate 308. The nitrogen layer 312 is situated at the interface between the BOX layer 302A and the handle substrate 308. The handle substrate 308 is heavily P++ doped and therefore provides a heavily P++ doped back gate region 308A. In some implementations, the back gate region 308A may use 1 Å to 50 Å or more of the handle substrate 308.

As such, in the implementation of the invention described by FIGS. 2 and 3A through 3H, the thin silicon device layer and the BOX layer do not suffer from ion implantation damage caused by boron ions, or other back gate doping ions, being implanted through both of these layers. Since the back gate doping does not occur though the thin silicon device layer, there is no residual concentration of doping ions in the thin silicon layer from ions that did not penetrate all the way through. And the inclusion of a nitrogen layer, in accordance with implementations of the invention, prevents a majority of the boron or other dopant ions in the base substrate from migrating up into the thin silicon device layer. The thin silicon device layer may therefore have a boron concentration (or any other P-type dopant concentration) that is less than 1×10¹⁵ cm⁻³, which is substantially less than conventional SOI substrates. In addition, the back gate region of the base silicon substrate may have a boron concentration (or any other P-type dopant concentration) that ranges from 1×10¹⁷ cm⁻³ to 1×10²⁰ cm⁻³.

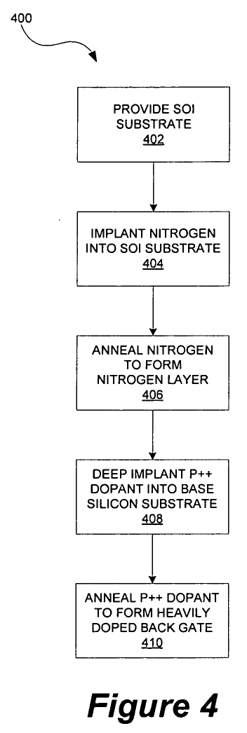

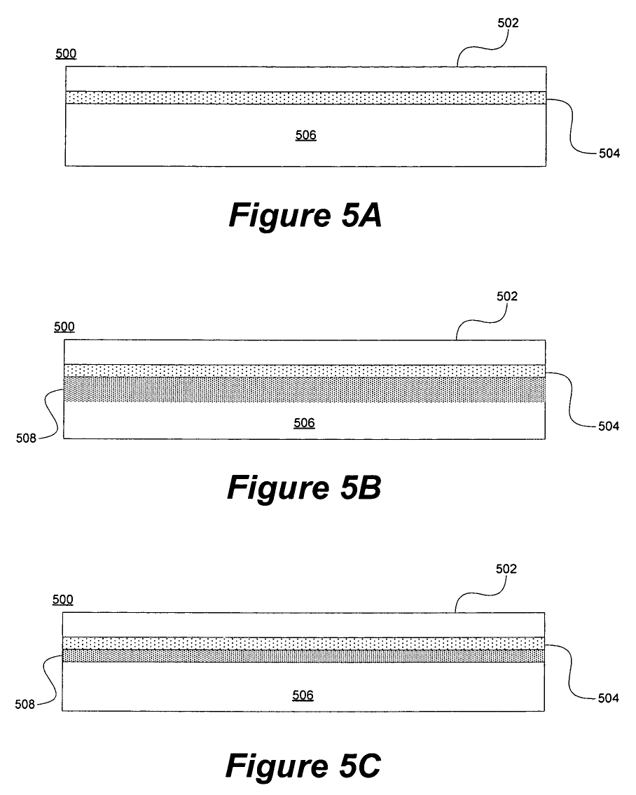

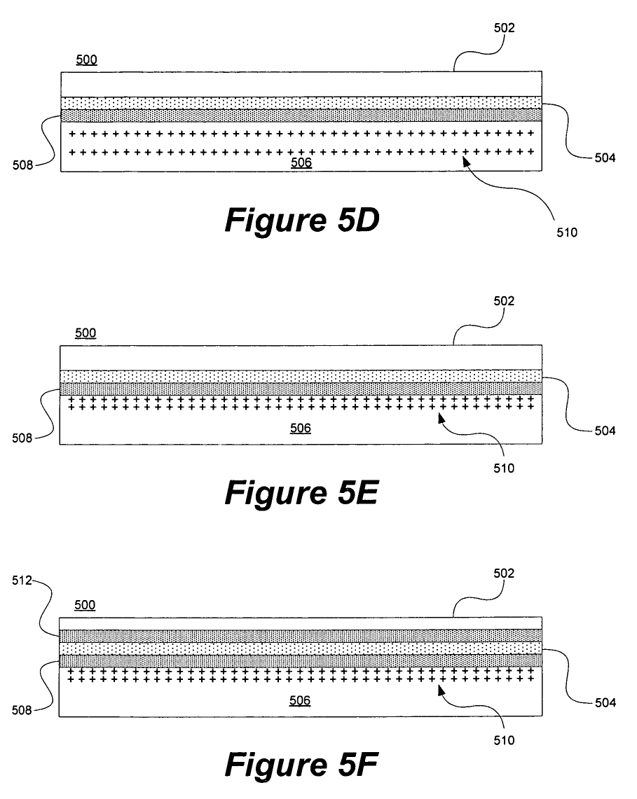

FIG. 4 is a method 400, according to another implementation of the invention, of forming an SOI wafer having a heavily doped P++ region that serves as a back gate for integrated circuit (IC) devices, such as FBCs. FIGS. 5A through 5E illustrate structures formed when the method of FIG. 4 is carried out.

The method 400 begins with an SOI substrate that includes a thin silicon device layer, a BOX layer, and a base silicon substrate (402), The thin silicon device layer and the base silicon substrate are generally crystalline semiconductor substrates that are formed using silicon. In other implementations, the thin silicon device layer and the base silicon substrate may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate may be formed are described here, any material that may serve as a foundation upon which a semiconductor device may be built falls within the spirit and scope of the present invention. FIG. 5A illustrates an SOI substrate 500 that includes a thin silicon device layer 502, a BOX layer 504, and a base silicon substrate 506.

An ion implantation process is carried out to implant nitrogen into the SOI substrate at a location proximate to the interface between the BOX layer and the base silicon substrate (404). The implanted nitrogen is then annealed to further drive the nitrogen to the interface between the BOX layer and the base silicon substrate where it forms a nitrogen layer (406). As described above, the nitrogen layer substantially prevents the migration or diffusion of P-type dopants such as boron. FIG. 5B illustrates the SOI substrate 500 having implanted nitrogen 508. FIG. 5C illustrates the SOI substrate 500 after the annealing process forms a nitrogen layer 508 along the interface between the BOX layer 504 and the base silicon substrate 506.

Another ion implantation process is carried out to heavily dope the base silicon substrate (408). A P-type dopant such as boron may be used to heavily dope the base silicon substrate and form a heavily doped P++ region. In accordance with implementations of the invention, the ion implantation process uses a relatively high implant energy that is sufficient to drive the boron deep and cause the boron peak to be deep within the base silicon substrate. This enables the majority of the boron to reach the base silicon substrate and maintains a relatively low concentration of residual boron in the thin silicon device layer. For instance, in implementations of the invention, the ion implantation process uses a high enough implant energy that the residual boron concentration in the thin silicon device layer is less than 1×10¹⁷ cm⁻³. In further implementations of the invention, the residual boron concentration in the thin silicon device layer is between 1×10¹⁶ cm⁻³ and 1×10¹⁷ cm⁻³. FIG. 5D illustrates the SOI substrate 500 after a high-energy ion implantation process implants a P-type dopant 510 into the base silicon substrate 506 at a relatively large depth.

Though the implementations described herein use a P-type doping, it should be noted that in some implementations an N-type doping may be used instead (to form an N++ doped region). Therefore the scope of the invention is not limited to P++ handle substrates.

An annealing process is then used to drive the boron (or other P++ dopant) to the interface between the BOX layer and the base silicon substrate, where the nitrogen layer is located (410). Even though the boron implantation process may have implanted the boron at a relatively large depth within the base silicon substrate, the annealing process efficiently brings the boron back to the interface where the boron accumulates and forms a heavily doped P++ region. This P++ doped region will serve as a back gate for devices formed on the thin silicon device layer. Meanwhile, the earlier formed nitrogen layer effectively prevents the boron from diffusing out of the base silicon substrate, thereby protecting the thin silicon device layer. In accordance with implementations of the invention, this nitrogen layer enables a high boron concentration to be produced at the back gate region without negatively impacting the thin silicon device layer. FIG. 5E illustrates the SOI substrate 500 after an annealing process causes the P-type dopant 510 to move toward the interface between the BOX layer 504 and the base silicon substrate 506 where the nitrogen layer 508 is now located.

In alternate implementations of the invention, a single annealing process may be used to simultaneously form the nitrogen layer and to drive the boron dopant back to the interface between the BOX layer and the base silicon substrate.

As such, in the implementation of the invention described by FIGS. 4 and 5A through 5E, the inclusion of a nitrogen layer substantially prevents boron or other dopant ions from migrating up into the thin silicon device layer. In this implementation of the invention, even though the boron is implanted through the thin silicon device layer, a high implantation energy is used to drive the boron deep into the base silicon substrate. Therefore, the thin silicon device layer may therefore have a boron concentration (or any other P-type dopant concentration) that is less than 1×10¹⁷ cm⁻³, and may even be less than 2×10¹⁶ cm⁻³, which is substantially less than conventional SOI substrates. In addition, the back gate region of the base silicon substrate may have a boron concentration (or any other P-type dopant concentration) that ranges from 1×10¹⁷ cm⁻³ to 1×10²⁰ cm⁻³.

In a further implementation of the invention, a second nitrogen layer may be formed at the interface between the thin silicon device layer and the BOX layer. This second nitrogen layer may provide an additional barrier to prevent boron, or another dopant, from migrating out of the base silicon substrate and into the thin silicon device layer. In one implementation, the second nitrogen layer may be formed by diffusing or implanting nitrogen into the thin silicon device layer and then using an annealing process to form the nitrogen layer. During the anneal, the nitrogen will migrate toward the interface between the thin silicon device layer and the BOX layer. At this interface, the nitrogen will accumulate and form the second nitrogen layer. FIG. 5F illustrates a second nitrogen layer 512 that has formed at the interface between the thin silicon device layer 502 and the BOX layer 504.

As such, methods and apparatuses have been described that provide an SOI substrate having a highly doped P++ back gate and a substantially undoped or relatively low doped thin silicon device layer. Unlike conventional methods that use ion implantation processes to dope the back gate, and therefore need to compromise by having a lower than desired doping concentration in the back gate and a higher than desired doping concentration in the thin silicon layer, the implementations of the invention incorporate nitrogen layers that substantially prevent the P-type dopant from leaving the back gate region. This yields the highest doping concentration where it is needed—in the back gate region. Implementations of the invention therefore provide an SOI substrate where no compromises need to be made—the back gate can have as high as concentration of doping ions as desired while the thin silicon layer may remain substantially free of the back gate doping ions. The methods of the invention are also non-invasive, so ion implantation damage to the thin silicon layer and the BOX layer is substantially reduced or eliminated.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A silicon-on-insulator (SOI) substrate comprising:
a base silicon substrate having a back gate region, wherein the back gate region has a first dopant concentration that is greater than 1×10¹⁷ cm⁻³;
a nitrogen layer adjacent to the back gate region of the base silicon substrate;
a BOX layer adjacent to the nitrogen layer; and
a thin silicon device layer adjacent to the BOX layer, wherein the thin silicon device layer has a first dopant concentration that is less than 1×10¹⁷ cm⁻³.

2. The SOI substrate of claim 1, wherein the thin silicon device layer has a first dopant concentration that is less than 2×10¹⁶ cm⁻³.

3. The SOI substrate of claim 1, wherein the thin silicon device layer has a first dopant concentration that is less than 1×10¹⁵ cm⁻³.

4. The SOI substrate of claim 1, wherein the first dopant comprises a P-type dopant.

5. The SOI substrate of claim 1, wherein the first dopant comprises boron.

6. The SOI substrate of claim 1, wherein the back gate region is a P++ region.

7. A silicon-on-insulator (SOI) substrate comprising:
a base silicon substrate having a back gate region, wherein the back gate region has a first dopant concentration that is greater than 1×10¹⁷ cm⁻³;
a first nitrogen layer adjacent to the back gate region of the base silicon substrate;
a BOX layer adjacent to the first nitrogen layer;
a second nitrogen layer adjacent to the BOX layer; and
a thin silicon device layer adjacent to the second nitrogen layer, wherein the thin silicon device layer has a first dopant concentration that is less than 1×10¹⁷ cm⁻³.

8. The SOI substrate of claim 7, wherein the thin silicon device layer has a first dopant concentration that is less than 2×10¹⁶ cm⁻³.

9. The SOI substrate of claim 7, wherein the thin silicon device layer has a first dopant concentration that is less than 1×10¹⁵ cm⁻³.

10. The SOI substrate of claim 7, wherein the first dopant comprises a P-type dopant.

11. The SOI substrate of claim 7, wherein the first dopant comprises boron.

12. The SOI substrate of claim 7, wherein the back gate region is a P++ region.
